(19) United States
(12) Patent Application Publication
(10) Pub. No.: US 2015/0093877 A1
(43) Pub. Date: Apr. 2, 2015

(54) METHOD FOR MANUFACTURING A SEMICONDUCTOR DEVICE BY STOPPING PLANARIZATION OF INSULATING MATERIAL ON FINS

(71) Applicant: GLOBALFOUNDRIES Inc., Grand Cayman (KY)

(72) Inventors: Haigou HUANG, Rexford, NY (US); Huang LIU, Mechanicville, NY (US); Hongliang SHEN, Ballston Lake, NY (US); Yongsik MOON, Loudonville, NY (US)

(73) Assignee: GLOBALFOUNDRIES Inc., Grand Cayman (KY)

(21) Appl. No.: 14/042,997

(22) Filed: Oct. 1, 2013

(51) Int. Cl. H01L 21/762

(52) U.S. Cl. CPC H01L 21/76224
USPC 438/424

(57) ABSTRACT

A method for fabricating a semiconductor device is provided, including forming a mask on a surface of a semiconductor substrate, creating isolation trenches within the substrate, and removing the mask from the substrate before depositing an insulating material within the trenches. The insulating material is then planarized to form a surface that is substantially coplanar with the surface of the semiconductor substrate.

### FIELD OF THE INVENTION

The present invention relates to a method of fabricating semiconductor devices that involves removing a hard mask material from a semiconductor substrate before depositing an insulating material on it.

### BACKGROUND OF THE INVENTION

The manufacture of semiconductors typically involves fabricating trenches within a semiconductor substrate which electrically isolate various integrated circuits within a single chip or wafer. As the size of technology nodes continues to decrease, significant challenges continue to arise due to issues related to traditional semiconductor fabrication processing techniques, including issues related to lack of planarity or uniformity of isolation trenches between various integrated circuits and to eliminating gaps within insulating material placed within trenches.

### BRIEF SUMMARY

In one embodiment, a method is provided. The method includes forming a mask on a surface of a semiconductor substrate; creating one or more isolation trenches within the substrate; removing the mask from the substrate; depositing an insulating material within the trenches that extends above the surface of the substrate; and planarizing the insulating material to form a planar surface that is substantially coplanar with the surface of the substrate.

In another embodiment, a method is provided. The method includes forming a silicon nitride mask on a surface of a semiconductor substrate; creating isolation trenches separated by fins in the substrate; removing the mask from the substrate; depositing an insulating material within and above the trenches and on the fins; planarizing the insulating material by chemical mechanical polishing and stopping on the fins to form a surface that is substantially coplanar with the surface of the fins; and cleaning the surface of the fins.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings, which are not necessarily drawn to scale, in which:

FIG. 1A is a cross-sectional elevation view of one embodiment of a conventional intermediate structure, including a semiconductor substrate and at least one isolation trench within the semiconductor substrate, obtained during an early stage of fabrication, in fabricating one or more semiconductor devices;

FIG. 1B depicts the structure of FIG. 1A with an insulating material having been provided for use in, for instance, fabricating one or more conventional semiconductor devices;

FIG. 1C depicts the structure of FIG. 1B after planarization of insulating material;

FIG. 1D depicts the structure of FIG. 1C after removal of a portion of insulating material;

FIG. 1E depicts the structure of FIG. 1D with the protective hard mask having been removed;

FIG. 1F depicts the resultant structure of FIG. 1E after an additional planarization step;

FIG. 2A is a cross-sectional elevation view of one embodiment of a conventional intermediate structure, including a semiconductor substrate and at least one isolation trench within the semiconductor substrate, obtained during an early stage of fabrication, in fabricating one or more semiconductor devices, in accordance with one or more aspects of the current invention;

FIG. 2B depicts the structure of FIG. 2A with the protective hard mask having been removed, in accordance with one or more aspects of the current invention;

FIG. 2C depicts the structure of FIG. 2B with an insulating material having been provided for use in, for instance, fabricating one or more conventional semiconductor devices, in accordance with one or more aspects of the current invention;

FIG. 2D depicts the resultant structure of FIG. 2C after planarization thereof, in accordance with one or more aspects of the current invention.

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

In one aspect, an early stage of semiconductor fabrication involves formation of isolation trenches within a semiconductor substrate that serve to electrically isolate multiple circuits within a single wafer or chip. For example, isolation trenches may be created in the surface of a semiconductor material, followed by placement of insulating material such as silicon oxide within the isolation trenches. Conventional processes for creating isolation trenches during semiconductor fabrication present several disadvantages. For example, uniformity between isolation trenches is desired but can be difficult to obtain by conventional methods. Furthermore, depositing insulating material in isolation trenches can be complicated by a problem known as gap fill, which may involve the formation of undesirable spaces or gaps within the insulating material deposited in isolation trenches.

Conventionally, recesses in a semiconductor substrate are first created in selected regions of a semiconductor substrate. For example, a hard mask may be directly or indirectly deposited on the semiconductor substrate and then a selective lithographic process may be used to form a pattern in the hard mask to distinguish between where isolation trenches will and will not be made in the underlying substrate. Isolation trenches created in this manner are thereby separated by fins that have hard mask material present on the upper surfaces.

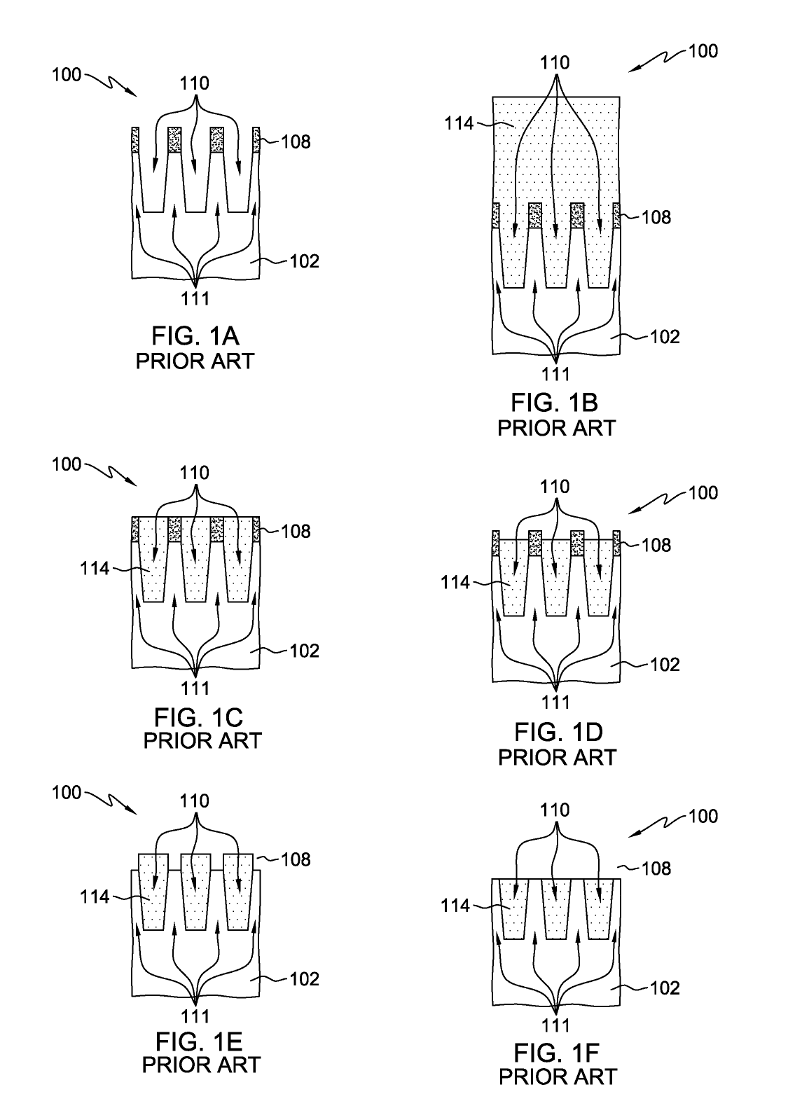

By way of example, FIGS. 1A-1F depict one embodiment of a conventional process for use in, for instance, semiconductor fabrication processing.

One embodiment of an intermediate process structure 100 obtained during a conventional procedure for semiconductor device manufacture is depicted in FIG. 1A. Isolation trenches 110, separated by fins 111, were created in a semiconductor substrate 102, such as a silicon-based substrate. Although not depicted in figures, one skilled in the art would know that isolation trenches 110 may have been created by one or more lithographic steps, which involve patterning a hard mask material 108. Hard mask material may be composed of, for example, silicon nitride, and lithographic steps may include, for example, providing patterned antireflective and photoresist layers over the hard mask to facilitate etching a pattern in the semiconductor substrate 102, and leaving a layer of hard mask 108 which may be several hundred angstroms thick atop fins 111.

As depicted in FIG. 1B, an insulating material 114 is then provided within and over the isolation trenches within the semiconductor substrate 102. This insulating material 114 may be deposited using a variety of techniques, such as, for example, chemical vapor deposition (CVD), plasma-enhanced CVD, or sub-atmospheric pressure thermal CVD (SACVD) processes and the thickness of a layer above protective hard mask 108, may be sufficient to allow for subsequent planarization of the structure. By way of example, insulating material 114 may be fabricated of or include an oxide material. For instance, high-density plasma (HDP) oxide, high aspect ratio process (HARP)-oxide or tetraethyl orthosilicate (TEOS)-based silicon dioxide may be deposited as insulating material 114 within and above the isolation trenches and the hard mask-topped fins. In effect, the presence of hard mask 108 atop fins 111 during an insulating material deposing step results in a deeper trench that needs to be filled with insulating material, which can disadvantageously exacerbate difficulties associated with gap fill.

As illustrated in FIG. 1C, a chemical-mechanical polish or an etch-back polish is then employed to polish away excess insulating material 114 from above the hard mask 108, using (in one embodiment) the protective hard masks atop the upper surfaces of the fins 111 as an etch stop. Conventionally, however, the microloading process by which hard mask material 108 was deposited on semiconductor substrate 102 may result in undesirable heterogeneity in the thickness of hard mask material 108 atop fins 111 and, consequently, in a thickness of insulating material 114 that remains atop hard mask material 108 following a first chemical-mechanical polish or an etch-back polish step.

Thus, following a first chemical-mechanical polish or an etch-back polish step, residual insulating material 114 is then removed from hard mask material 108, as depicted in FIG. 1D. This removal process may be performed by employing a deglazing etching process using, for instance, a deglaze etchant that is highly selective to an oxide etching process. In one example, the etchant may be dilute hydrofluoric acid with a dilution of about 1:1000 to about 1:500. The deglazing etching process may be performed to remove any residual oxide from above the upper surfaces of protective hard mask 108, as well as recessing a portion of insulating material 114 to below the upper surfaces of hard mask 108 atop fins 111, and to expose protective hard mask 108 for a subsequent removal process. Disadvantageously, however, this deglazing etching process is not a complete etch process. Thus, it results only in partial removal of insulating material 114 that remains above a hypothetical plane that extends across the tops of fins 111, and an undesirable variation in the distance between the surface of insulating material 114 and such hypothetical plane.

As depicted in FIG. 1E, exposed protective hard mask 108 is next selectively removed from atop fins 111 by a selective etch process. By way of an example, protective hard mask 108 may be selectively removed using hot phosphoric acid. The undesirable height variations caused by above-described deglazing process results in non-planarity or non-uniformity of the surfaces of insulating material.

As illustrated in FIG. 1F, an additional chemical-mechanical polishing is therefore performed to remove remaining insulating material 114 from above a hypothetical plane that extends across the tops of fins 111. This additional chemical-mechanical polishing is performed to result in the surfaces of insulating material 114 within isolation trenches 110 to be coplanar with the surfaces of fins 111. However, because of an undesirable variation in the distance between the surface of insulating material 114 and a hypothetical plane extending across the top of fins 111 that may result from the deglazing step, a lack of planarity or uniformity of the resultant semiconductor structure may disadvantageously results from this additional chemical-mechanical polishing step. Such lack of planarity or uniformity may result in undesirable thickness variations across a semiconductor device during subsequent fabrication processing.

Although not depicted, one skilled in the art would know that additional layers of material may be provided on or within the structure 100 depicted in FIGS. 1A-1F during the fabrication process. Nonlimiting examples of such layers may include: a thin oxide layer (also referred to as pad oxide) disposed between semiconductor substrate 102 and hard mask 108 to protect the semiconductor substrate 102 during processing; and an isolation liner layer disposed along the sidewalls of hard mask material 108 and the sides and base of isolation trench 110. “Isolation liner” refers generally to any film or layer which may form part of the resultant isolation trench and may be, for example, a thin layer of silicon dioxide grown by thermal oxidation. Layers may also be formed using a variety of different materials and fabrication techniques, such as chemical vapor deposition (CVD), atomic layer deposition (ALD), physical vapor deposition (PVD) or plasma-enhanced versions of such processes. The thickness of the depicted layers may also vary, depending on the particular application.

As further explained below, the methods disclosed herein in accordance with aspects of the invention address challenges in semiconductor fabrication processing and thereby enhance the use of isolation trenches in advanced technology nodes. In accordance with some aspects of the present invention, some conventional processing steps as described above, including planarization and deglazing, may be eliminated, while surprisingly superior isolation region uniformity results may be provided and complications associated with gap fill may be reduced.

Generally stated, disclosed herein, in one example, is a method which includes: patterning a semiconductor substrate to form a plurality of isolation trenches within the semiconductor substrate separated by fins, the patterning including leaving, at least in part, a protective hard mask atop fins; selectively removing the hard mask material; and providing an insulating material within the plurality of isolation trenches and above the plurality of isolation trenches and fins; and planarizing the insulating material to facilitate fabricating an isolation trench within the semiconductor substrate, and stopping the planarizing on the fins.

In one example, patterning the semiconductor substrate includes selectively etching through a portion of a protective hard mask and a portion of the semiconductor substrate to create at least one isolation trench within the semiconductor substrate, while leaving, at least in part, the protective hard mask above a portion of the semiconductor substrate. The protective mask may be fabricated of or includes a nitride material, and may have a thickness of between about 30 nanometers to about 60 nanometers, inclusively.

In one aspect, the protective hard mask is selectively removed from the semiconductor substrate, such as by using hot phosphoric acid. The height of an isolation trench after removal of hard mask material is defined as the distance from the base of the trench to a hypothetical plane that is coplanar with the surface of portions of the semiconductor substrate that were not etched to create an isolation trench. Insulating material, such as an oxide material, is next provided within and substantially above the top of at least one isolation trench and, optionally, may also be provided atop the surface of at least one other portion of the semiconductor substrate that was not etched to create an isolation trench. Exposed surface of insulating material is then selectively planarized to be substantially coplanar with the surface of portions of semiconductor substrate that were not etched to create an isolation trench, which serve as the planarization stop. In one example, providing insulating material may include leaving the portion of the insulating material over the at least one isolation trench having a thickness above the height of the isolation trench of about 200 nanometers to about 300 nanometers.

In one aspect, planarizing includes chemical-mechanical polishing or etch back polishing. Polishing may include use of a slurry, such as ceria slurry. Polishing may involve a process that is selective for insulating material over semiconductor substrate material. In another aspect, an exposed surface of semiconductor material may be cleaned following planarization. Cleaning may comprise use of dilute hydrofluoric acid or a standard cleaning solution known to one skilled in the art.

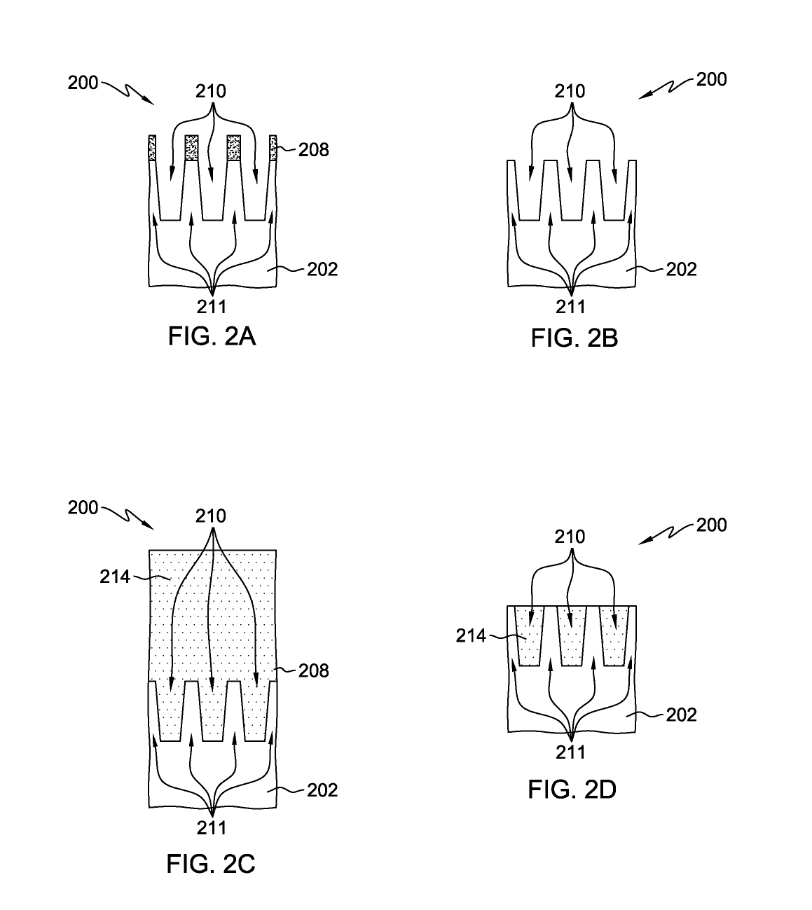

By way of example, FIGS. 2A-2D depict one embodiment of a process for use in, for instance, semiconductor fabrication processing in accordance with the present invention.

FIG. 2A illustrates an intermediate structure 200, attained during an early stage of semiconductor fabrication processing, in accordance with one or more aspects of the present invention. Intermediate structure 200 includes a semiconductor substrate 202, such as a bulk semiconductor material, for example, a bulk silicon wafer. In one example, semiconductor substrate 202 may include any silicon-containing substrate including, but not limited to, silicon (Si), single crystal silicon, polycrystalline Si, amorphous Si, silicon-on-nothing (SON), silicon-on-insulator (SOI), or silicon-on-replacement (SRI) substrates and the like. Semiconductor substrate 202 may in addition or instead include various isolations, dopings, and/or device features. The semiconductor substrate may include other suitable elementary semiconductors, such as, for example, germanium (Ge) in crystal, a compound semiconductor such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof

By way of example only, protective mask material 208 may have been deposited on semiconductor substrate 202, directly or indirectly, using conventional deposition processes, such as, for example, chemical vapor deposition (CVD), low-pressure CVD, or plasma-enhanced CVD (PE-CVD). In one example, protective mask material 208 may include or be fabricated of a material such as silicon nitride. In a specific example, silicon nitride may be deposited using process gases such as, for example, dichlorosilane (SiH₂Cl₂) and ammonia (NH₃) and using known process conditions. In another example, silicon nitride may also or alternatively be deposited using halogen-free precursor such as, for example, bis (t-butylamino)silane (BTBAS) (SiC₈N₂H₂₂) and ammonia (NH₃) at about 550° C.

Isolation trenches 210 are also formed within the substrate 202. Although not depicted in figures, one skilled in the art would know that isolation trenches 210 may have been created by one or more lithographic steps, which involve patterning hard mask material 208. Lithographic steps may include, for example, providing patterned antireflective and photoresist layers over the hard mask to facilitate etching a pattern in the semiconductor substrate 202, and leaving a layer of hard mask 208 which may be several hundred angstroms thick atop fins 211. Any suitable conventional anisotropic dry etching processes, such as reactive ion etching processes, may be employed to anisotropically etch through semiconductor substrate 202 to create isolation trenches 210. In a specific example, the reactive ion etching may be performed using fluorine based chemistry and involving gases such as tetrafluoromethane (CF₄), trifluoromethane (CHF₃), difluoromethane (CH₂F₂), fluoromethane (CH₃F), octofluoromethane (C₄F₈), hexafluoro-1,3-butadiene (C₄F₆), sulfur hexafluoride (SF₆) and oxygen (O₂).

As depicted in FIG. 2B, protective hard mask material 208 is next selectively removed from atop fins 211 by a selective etch process. By way of an example, protective hard mask 208 may be selectively removed using hot phosphoric acid. Undesirable heterogeneity in the thickness of hard mask material 208 that may have been caused when hard mask material 208 was deposited on semiconductor substrate 202 are no longer present following this removal of hard mask material 208. Advantageously, in one aspect, a cost prohibitive and time consuming deglazing step is also not required nor performed before hard mask removal.

As depicted in FIG. 2C, after removal of the hard mask material 208, an insulating material 214 may be provided within and substantially over laterally separated isolation trenches 210 within the semiconductor substrate and substantially over fins 211. This insulating material 214 may be deposited using a variety of techniques, such as, for example, chemical vapor deposition (CVD), plasma-enhanced CVD, or sub-atmospheric pressure thermal CVD (SACVD) processes and the thickness of the layer above protective hard mask 208, may be (in one example) sufficient to allow for subsequent planarization of the structure. By way of example, insulating material 214 may be fabricated of or include an oxide material. For instance, high-density plasma (HDP) oxide, high aspect ratio process (HARP)-oxide or tetraethyl orthosilicate (TEOS)-based silicon dioxide may be deposited as insulating material 214 within and substantially over isolation trenches 210, using plasma-enhanced CVD process. In a specific example, the chemical vapor deposition process may be employed using tetraethyl orthosilicate (TEOS) and ozone (O₃) as reactants to deposit the tetraethyl orthosilicate based silicon dioxide within and substantially over isolation trenches 210. In one aspect, removal of hard mask material before insulating material is provided may advantageously reduce problems associated with gap fill.

As illustrated in FIG. 2D, a selective chemical-mechanical polish or an etch-back polish may then be employed to polish away excess insulating material 214 from above the height of the isolation trenches 210 and fins 211, to form a surface of insulating material 214 that is substantially coplanar with the upper surfaces of fins 211, which serve as an etch stop. Selective in this context means the planarization step is selective for insulating material over semiconductor material. Planarization may involve use of a slurry, such as a ceria slurry. In another example, a selective etching process such as, for instance, planar reactive ion etching or a plasma etching process may be performed to remove excess insulating material and substantially coplanarize it with the upper surfaces of fins 211. In one aspect, advantageously, because hard mask material 208 was removed before insulating material 214 was provided, isolation trench uniformity may be enhanced and undesirable variations in intermediate semiconductor structure 200 following planarization may be minimized, thereby improving performance of a resulting semiconductor device.

Although not depicted, an exposed surface of semiconductor material may be cleaned following planarization. Cleaning may comprise use of dilute hydrofluoric acid or a standard cleaning solution known to one skilled in the art. Also although not depicted, one skilled in the art would know that additional layers of material may be provided on or within the structure 200 depicted in FIGS. 2A-2D during the fabrication process. Nonlimiting examples of such layers may include: a thin oxide layer (also referred to as pad oxide) disposed between semiconductor substrate 202 and hard mask 208 to protect the semiconductor substrate 202 during processing; and an isolation liner layer disposed along the sidewalls of hard mask material 208 and the sides and base of isolation trench 210. Layers may be formed using a variety of different materials and fabrication techniques, such as chemical vapor deposition (CVD), atomic layer deposition (ALD), physical vapor deposition (PVD) or plasma-enhanced versions of such processes. The thickness of the depicted layers may also vary, depending on the particular application. Although also not depicted, after planarization, a further portion of insulating material 214 from within isolation trenches 210 may be recessed to below the surface of fins 211.

Advantages of aspects of the present invention are that difficulties pertaining to gap fill are reduced, removal of insulating material from above hard mask material and deglazing before hard mask material removal are not required, and uniformity of semiconductor device are enhanced.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method comprising:
forming a mask on a surface of a silicon semiconductor substrate;
creating one or a plurality of isolation trenches in the substrate;
removing the mask from the substrate;
after removing the mask from the substrate, depositing a first layer of insulating material within at least one trench wherein the insulating material extends above the surface of the semiconductor substrate; and
before another layer of insulating material is deposited on the first layer of insulating material, planarizing the first layer of insulating material and stopping the planarizing directly on the silicon semiconductor substrate when a surface is formed that is substantially coplanar with the surface of the silicon semiconductor substrate.

2. The method of claim 1, wherein the mask comprises a silicon nitride.

3. The method of claim 1, wherein the first layer of insulating material comprises an oxide.

4. The method of claim 3, wherein planarizing comprises at least one of chemical mechanical polishing and etch back polishing.

5. The method of claim 4, wherein chemical mechanical polishing comprises using a slurry.

6. The method of claim 4, wherein a deglazing step does not occur before removing the hard mask.

7. The method of claim 5, wherein the slurry comprises a ceria slurry.

8. The method of claim 3, wherein depositing the oxide comprises using a chemical vapor deposition process.

9. The method of claim 1, further comprising cleaning the surface of the silicon semiconductor substrate after planarizing the first layer of insulating material.

10. The method of claim 9, wherein the mask comprises a silicon nitride.

11. The method of claim 9, wherein the first layer of insulating material comprises an oxide.

12. The method of claim 11, wherein planarizing comprises chemical mechanical polishing.

13. The method of claim 12, wherein chemical mechanical polishing comprises using a slurry.

14. The method of claim 12, wherein a deglazing step does not occur before removing the hard mask.

15. The method of claim 13, wherein the slurry comprises a ceria slurry.

16. The method of claim 11, wherein depositing the oxide comprises using a chemical vapor deposition process.

17. A method comprising:
forming a silicon nitride mask on a surface of a silicon semiconductor substrate;
creating a plurality of isolation trenches in the substrate, the isolation trenches being separated by one or more silicon fins therebetween;
removing the silicon nitride mask from the substrate;
depositing a first layer of oxide material within and above the trenches after removing the silicon nitride mask from the substrate;
before another layer of oxide material is deposited, planarizing the first layer of oxide material by chemical mechanical polishing and stopping the planarizing directly on the silicon semiconductor substrate when a surface that is substantially coplanar with a surface of the one or more silicon fins is formed; and
cleaning the surface of the one or more silicon fins.

18. The method of claim 17 wherein chemical mechanical polishing comprises using a slurry.

19. The method of claim 18 wherein the slurry comprises a ceria slurry.

20. The method of claim 17, wherein a deglazing step does not occur before removing the silicon nitride mask.
